(19) United States
(12) Patent Application Publication
(10) Pub. No.: US 2026/0044639 A1
(43) Pub. Date: Feb. 12, 2026

(54) METHOD AND DEVICE FOR 3D MODELING OF STRUCTURAL MEMBERS OF BUILDING

(71) Applicant: OZOMETA CO., LTD., Incheon (KR)

(72) Inventors: Suk NAMGUNG, Suwon-si (KR); Chang Gyu KIM, Yongin-si (KR); Chang Kook PARK, Seoul (KR)

(73) Assignee: OZOMETA CO., LTD., Incheon (KR)

(21) Appl. No.: 19/287,471

(22) Filed: Jul. 31, 2025

(30) Foreign Application Priority Data
Aug. 6, 2024 (KR) 10-2024-0104766

(51) Int. Cl. G06F 30/13

(52) U.S. Cl. CPC G06F 30/13

(57) ABSTRACT

Disclosed is a method for three-dimensional (3D) modeling of structural members of a building, which is performed by a processor. The method for 3D modeling of the structural members of the building, which is performed by the processor, includes extracting at least one of information on a material strength corresponding to use of the building and information on covering thicknesses of steel bars corresponding to the structural members of the building from a design drawing of the building, extracting information on shapes of the steel bars for the structural members from the design drawing, extracting location information on the structural members from the design drawing, and defining at least one of the information on the material strength, the information on the covering thicknesses, the information on the shapes of the steel bars, and the location information as data of the structural members, wherein, when the structural members constitute a column, the data of the structural members corresponds to the steel bars extending in a height direction of the column, and includes first information for determining whether to move the steel bars forming the column and display the steel bars on a display, the first information includes a first value that is displayed on the display without moving the steel bars and a second value that is displayed on the display after moving the steel bars, and is set so that the first value and the second value alternately correspond to the steel bars sequentially located in the height direction of the column.

### CROSS-REFERENCE TO RELATED APPLICATION

This application claims priority to and the benefit of Korean Patent Application No. 2024-0104766, filed on Aug. 6, 2024, the disclosure of which is incorporated herein by reference in its entirety.

### BACKGROUND

### 1. Field of the Invention

The present invention relates to a method and device for three-dimensional (3D) modeling of structural members of a building, and more particularly, to a method and device for 3D modeling of structural members of a building that can 3D-model the structural members of the building.

### 2. Discussion of Related Art

Conventional two-dimensional (2D) design-based modeling methods have had difficulty identifying errors in designs that are wrong due to limitations of 2D plans. Further, conventional 2D design-based modeling methods have had a problem in that it has been difficult to immediately reflect and respond to variables such as material changes in the field.

Not only have there been limitations to conventional 2D design-based modeling methods, but even conventional three-dimensional (3D) design-based modeling technology has had fundamental limitations in that it has been difficult to clearly visually grasp the interference, exact location, and construction errors of complex building structures, in particular, structural members that are densely arranged internally, such as steel bars. This was a main factor that delayed the discovery of errors during the design stage and increased the possibility of unnecessary rework and safety issues during on-site construction. In order to solve these problems, the present invention provides an innovative display method that takes into account the specific characteristics of structural members beyond simple 3D visualization, thereby dramatically improving design accuracy and construction efficiency.

### Document of Related Art

### Patent Document

(Patent Document 0001) Korean Laid-open Patent Publication No. 10-2021-0141892 (Published on Nov. 23, 2021)

### SUMMARY OF THE INVENTION

The present invention is directed to providing a method and device for three-dimensional (3D) modeling of structural members of a building that can 3D-model the structural members of the building.

According to an aspect of the present invention, there is provided a method for 3D modeling of structural members of a building performed by a processor, which includes extracting at least one of information on a material strength corresponding to use of the building and information on covering thicknesses of steel bars corresponding to the structural members of the building from a design drawing of the building, extracting information on shapes of the steel bars for the structural members from the design drawing, extracting location information on the structural members from the design drawing, and defining at least one of the information on the material strength, the information on the covering thicknesses, the information on the shapes of the steel bars, and the location information as data of the structural members, wherein, when the structural members constitute a column, the data of the structural members corresponds to the steel bars extending in a height direction of the column, and includes first information for determining whether to move the steel bars forming the column and display the steel bars on a display, and the first information includes a first value that is displayed on the display without moving the steel bars and a second value that is displayed on the display after moving the steel bars, and is set so that the first value and the second value alternately correspond to the steel bars sequentially located in the height direction of the column. The location information may include coordinates of a location at which the column is located in the building and a height section in which the steel bars are located in the column, wherein the height section may be a range of values in which the steel bars are arranged in the height direction of the column, and the method may further include determining an order in which the steel bars are arranged in the height direction of the column using the height section of the steel bars. The steel bars forming the column may include first steel bars and second steel bars that are adjacent to each other in the height direction of the column, and when the first value corresponds to the first steel bars and the second value corresponds to the second steel bars, the second steel bars may be moved to be misaligned with the first steel bars in the height direction of the column but overlap at least a portion of the first steel bars, and may be displayed on the display.

The information on the shapes of the steel bars may include a shape in a first direction of the steel bars and a shape in a second direction of the steel bars, the shape in the first direction of the steel bar may be a shape of the steel bar in a direction into the display among the steel bars, and include one of shapes included in a steel bar shape database in which shapes of vertical bars and shapes of horizontal bars are stored, and the shape in the second direction of the steel bar may be a shape of the steel bar in a direction out of the display among the steel bars, and include one of the shape included in the steel bar shape database. When the structural members constitute a wall, the data of the structural members may further include second information on a connection relationship between the steel bars forming the wall, wherein the second information includes at least one of a third value that is displayed on the display so that two steel bars that are arranged adjacently and coupled to each other are misaligned with each other in one direction but at least portions thereof overlap each other, and a fourth value that is displayed on the display so that the two steel bars are in contact with each other in the one direction but a reinforcing steel bar is added to the contact area.

According to another aspect of the present invention, there is provided a computing device, which includes a memory configured to store commands for 3D modeling of structural members of a building, and a processor configured to execute the commands, wherein the commands are configured to extract at least one of information on a material strength corresponding to use of the building and information on covering thicknesses of steel bars corresponding to the structural members of the building from a design drawing of the building, extract information on shapes of the steel bars for the structural members from the design drawing, extract location information on the structural members from the design drawing, and define at least one of the information on the material strength, the information on the covering thicknesses, the information on the shapes of the steel bars, and the location information as data of the structural members, wherein, when the structural members constitute a column, the data of the structural members corresponds to the steel bars extending in a height direction of the column, and includes first information for determining whether to move the steel bars forming the column and display the steel bars on a display, and the first information includes a first value that is displayed on the display without moving the steel bars and a second value that is displayed on the display after moving the steel bars, and is set so that the first value and the second value alternately correspond to the steel bars sequentially located in the height direction of the column. The location information may include coordinates of a location at which the column is located in the building and a height section in which the steel bars are located in the column, wherein the height section may be a range of values in which the steel bars are arranged in the height direction of the column, and the commands may be configured to determine an order in which the steel bars are arranged in the height direction of the column using the height section of the steel bars. The steel bars forming the column may include first steel bars and second steel bars that are adjacent to each other in the height direction of the column, and when the first value corresponds to the first steel bars and the second value corresponds to the second steel bars, the commands may be configured so that the second steel bars are moved to be misaligned with the first steel bars in the height direction of the column but overlap at least a portion of the first steel bars, and are displayed on the display. The memory may include a steel bar shape database in which shapes of vertical bars and shapes of horizontal bars are stored, the information on the shapes of the steel bars may include shapes in a first direction of the steel bars and shapes in a second direction of the steel bars, the shape in the first direction of the steel bar may be a shape of the steel bar in a direction into the display among the steel bars, and include one of the shapes included in the steel bar shape database, and the shape in the second direction of the steel bar may be a shape of the steel bar in a direction out of the display among the steel bars, and include one of the shapes included in the steel bar shape database. When the structural members constitute a wall, the data of the structural members may further include second information on a connection relationship between the steel bars forming the wall, wherein the second information may include at least one of a third value that is displayed on the display so that two steel bars that are arranged adjacently and coupled to each other are misaligned with each other in one direction but at least portions thereof overlap each other, and a fourth value that is displayed on the display so that the two steel bars are in contact with each other in the one direction but a reinforcing steel bar is added to the contact area.

### BRIEF DESCRIPTION OF THE DRAWINGS

In order to more fully understand the drawings cited in the Detailed Description of the Present Invention, a detailed description of each drawing is provided.

The above and other objects, features and advantages of the present invention will become more apparent to those of ordinary skill in the art by describing exemplary embodiments thereof in detail with reference to the accompanying drawings, in which:

FIG. 1 illustrates a block diagram of a computing device according to one embodiment of the present invention;

FIGS. 2A and 2B illustrate various shapes of vertical bars and various shapes of horizontal bars;

FIG. 3 shows a table for describing an operation of allowing the computing device illustrated in FIG. 1 to define data of structural members;

FIGS. 4A and 4B show columns displayed on a display of the computing device illustrated in FIG. 1 to describe other data of structural members;

FIGS. 5A and 5B show walls displayed on the display of the computing device illustrated in FIG. 1 to describe still other data of the structural members;

FIGS. 6A and 6B show walls displayed on the display of the computing device illustrated in FIG. 1 to describe yet other data of the structural members;

FIGS. 7A and 7B show walls displayed on the display of the computing device illustrated in FIG. 1 to describe yet other data of the structural members;

FIGS. 8A, 8B, and 8C show walls displayed on the display of the computing device illustrated in FIG. 1 to describe structural members that are changed when the design of the building is changed;

FIG. 9 illustrates a flowchart for describing a method for three-dimensional (3D) modeling of structural members of a building of the present invention; and

FIG. 10 shows 3D modeled structural members of the building that are displayed on the display illustrated in FIG. 1.

### DETAILED DESCRIPTION OF EXEMPLARY EMBODIMENTS

Specific structural and functional descriptions of embodiments of the present invention disclosed in this specification are only for the purpose of describing the embodiments of the present invention, and the embodiments of the present invention may be embodied in various forms and are not to be construed as limited to the embodiments described in this specification.

It should be understood that, although the terms “first,” “second,” and the like may be used herein to describe various elements, the elements are not limited by the terms. The terms are only used to distinguish one element from another element. For example, a first element could be termed a second element, and similarly, a second element could be termed a first element without departing from the scope of the present invention.

It should be understood that when an element is referred to as being “connected” or “coupled” to another element, the element may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” and the like.).

The terminology used herein is for the purpose of describing particular embodiments only and is not intended to be limiting to the present invention. As used herein, the singular forms “a” and “an” are intended to also include the plural forms, unless the context clearly indicates otherwise. It should be further understood that the terms “comprise,” “comprising,” “include,” and/or “including,” when used herein, specify the presence of stated features, integers, steps, operations, elements, parts, or combinations thereof, but do not preclude the presence or addition of one or more other features, integers, steps, operations, elements, parts, or combinations thereof.

Unless otherwise defined, all terms including technical and scientific terms used herein have the same meaning as commonly understood by one of ordinary skill in the art to which the present invention belongs. It should be further understood that terms, such as those defined in commonly used dictionaries, should be interpreted as having meanings that are consistent with their meanings in the context of the relevant art and are not to be interpreted in an idealized or overly formal sense unless expressly so defined herein.

Hereinafter, the present invention will be described in detail by describing exemplary embodiments of the present invention with reference to the accompanying drawings.

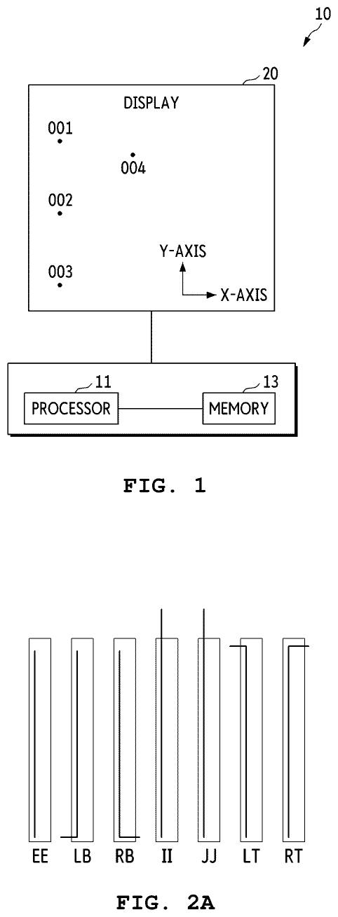

FIG. 1 illustrates a block diagram of a computing device according to one embodiment of the present invention.

Referring to FIG. 1, a computing device 10 may define data of structural members of a building and three-dimensional (3D)-model the structural members on a display 20 according to the defined data. The computing device 10 includes a processor 11 for executing commands for 3D modeling of the structural members of the building, a memory 13 for storing the commands, and the display 20. The computing device 10 is an electronic device such as a smartphone, a tablet personal computer (PC), a server, a notebook computer, a PC, a desktop computer, or the like. A user is a person who uses the computing device 10. The building may be an apartment. The data of the structural members may be a structure in a program defined by the computing device 10.

The processor 11 reads design drawings of the building that are stored in the memory 13. The computing device 10 may receive the design drawings of the building via a network (not illustrated).

The design drawings include architectural design drawings and structural design drawings. The architectural design drawings include floor plans, location plans, cross sections, or elevations. The structural design drawings include general structural information, column layout drawings, structural plans, and the steel bar arrangement lists. The general structural information includes an outline of the building, design criteria, material strength, covering thicknesses of steel bars, steel bar processing, joints and anchorage lengths of the steel bars, etc. The column layout drawings are drawings that show installation locations and shapes of columns. The structural plans are plans for structural members. The structural members are foundations, walls, columns, or floors of a building.

The processor 11 extracts location information on the structural members of the building from the design drawings of the building. The location information on the structural members is information on locations at which the structural members should be located. In some embodiments, the location information may be information on a region in which a wall is located, and coordinates of four vertices at which the wall is located are indicated as (x, y). The location information on the structural members may be included in a structural plan, a column layout drawing, etc. The extraction operation is an operation in which the processor 11 searches for related content in the design drawings and reads a value (e.g., location information or the like) corresponding to the related content. The design drawing may be a file. In some embodiments, the processor 11 may recognize the structural members depicted in the design drawings, calculate a relative location relationship, and extract the calculated relative location relationship as the location information.

The processor 11 extracts at least one of a material strength corresponding to use of the building and information on covering thicknesses of the steel bars corresponding to the structural members of the building from the design drawings of the building.

Specifically, the material strength corresponding to the use of the building or the covering thicknesses of the steel bars are included in the structural design drawings. The material strength is the strength of concrete or the strength of the steel bar.

The material strength, that is, the strength of concrete or the strength of the steel bar, may vary according to the use of the building. In some embodiments, when the building is an apartment, the use of the apartment may be divided into an apartment region, which is a residential region in which residents live, an underground parking lot, resident common facilities, and neighborhood living facilities. The material strength may vary according to the apartment region, the underground parking lot, the resident common facilities, and the neighborhood living facilities, which are the uses of the apartment. A material strength of a wall in the apartment region, which is the residential region, may be 24 MPa, and a material strength of an inner column in the underground parking lot may be 30 MPa. The above material strength, 24 MPa or 30 MPa, may be the strength of concrete.

The covering thicknesses may vary according to the structural members of the building. In some embodiments, covering thicknesses of the steel bars corresponding to beams, columns, or foundations may be 40 mm, and covering thicknesses of the steel bars corresponding to walls may be 20 mm.

The processor 11 extracts information on member directions of the structural members from the design drawings.

The processor 11 extracts information on shapes of the steel bars for the structural members from the design drawings.

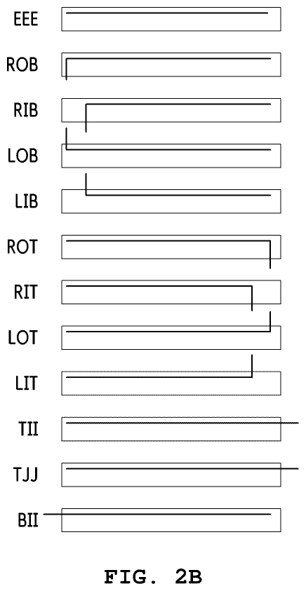

FIGS. 2A and 2B illustrate various shapes of vertical bars and various shapes of horizontal bars. FIG. 2A illustrates various shapes of vertical bars. FIG. 2B illustrates various shapes of horizontal bars. Various shapes of vertical bars and various shapes of horizontal bars may be stored in a steel bar shape database. The steel bar shape database may be stored in the memory 13.

Referring to FIGS. 1 and 2, the design drawings may include at least one of a plurality of shapes illustrated in FIG. 2. Different vertical bars and horizontal bars may be given respective names. In some embodiments, the names may be “EE,” “LB,” “RB,” or “II.”

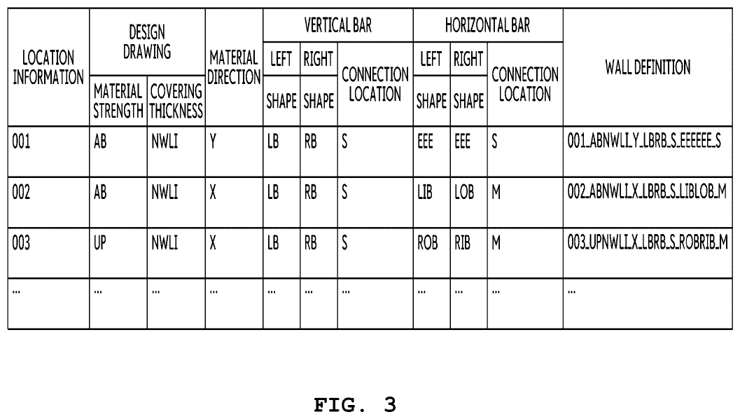

FIG. 3 shows a table for describing an operation of allowing the computing device illustrated in FIG. 1 to define data of structural members.

Referring to FIGS. 1 to 3, the processor 11 defines the data of the structural members by merging the extracted material strength, information on the covering thicknesses, and information on the shapes of the steel bars. FIG. 3 shows data on walls among the structural members.

In some embodiments, the processor 11 may extract the information on the member directions of the structural members from the design drawings and add the extracted information on the member directions to the defined data of the structural members. In some embodiments, the processor 11 may extract the location information on structural members of the building from the design drawings of the building and add the extracted location information to the defined data of the structural members.

That is, the data on the walls defined in FIG. 3 includes the location information, the material strength, the covering thickness, the member direction, and the shape of the steel bar. The shape of the steel bar includes a left side of the vertical bar, a right side of the vertical bar, a left side of the horizontal bar, and a right side of the horizontal bar. That is, the wall is defined by specific properties of the steel bars (location information, material strength, covering thickness, member direction, left side of the vertical bar, right side of the vertical bar, left side of the horizontal bar, and right side of the horizontal bar).

Further, the data on the walls defined in FIG. 3 may further include a length of the vertical bar. The length of the vertical bar is used as the Z coordinate in the display 20, and therefore the structural members may be 3D-modeled using the location information and the length of the vertical bar.

The location information may be extracted from the design drawings of the building, and the location information defined in FIG. 3 is information on a location displayed on the display 20. The location information may be expressed as 2D coordinates (X, Y) on the display 20, and the order of the location information may be displayed as a number, such as “001.” In FIG. 1, the number “001” indicates a location at which the structural member is displayed.

The material strength may correspond to the use of the building. “AB” indicates a material strength corresponding to the ground floor of an apartment, and “UP” indicates a material strength corresponding to an underground parking lot. The material strengths for “AB” and “UP” are different.

The covering thickness may correspond to the structural member of the building. “NWLI” indicates a covering thickness for an interior of a wall, and “NWLO” indicates a covering thickness for an exterior of the wall.

The member direction may correspond to a direction of the structural member. In some embodiments, when the structural member is a wall, “Y” indicates that the wall is vertical and “X” indicates that the wall is horizontal. The member direction may be extracted from the design drawings.

The shape of the steel bar may be expressed in a basic form. The basic form is a form defined in the data of the structural members, and may be expressed in a rotated form in the 3D model. The shape of the steel bar may be defined by dividing the shape into a left shape and a right shape. The left shape of the steel bar may be defined as a left side of the steel bar or a shape in a first direction of the steel bar, and the right shape of the steel bar may be defined as a right side of the steel bar or a shape in a second direction of the steel bar. The left is the first direction and may be a direction into the display 20, and the right is the second direction and may be a direction out of the display 20. The left side of the steel bar and the right side of the steel bar may each include one of shapes included in the steel bar shape database.

The left side of the vertical bar and the right side of the vertical bar may each be defined. The left side of the vertical bar and the right side of the vertical bar may be defined differently. The left side of the vertical bar and the right side of the vertical bar may each include one of the shapes illustrated in FIG. 2A. In some embodiments, the left side of the vertical bar may be defined as “LB,” and the right side of the vertical bar may be defined as “RB.”

The left side of the horizontal bar and the right side of the horizontal bar may each be defined. The left side of the horizontal bar and the right side of the horizontal bar may be defined differently. The left side of the horizontal bar and the right side of the horizontal bar may each include one of the shapes illustrated in FIG. 2B.

In some embodiments, the data on the walls defined in FIG. 3 may further include information for determining whether to move the vertical or horizontal bar and display the vertical or horizontal bar on the display 20. In FIG. 3, whether to move the vertical or horizontal bar and display the vertical or horizontal bar on the display 20 is indicated by “S” or “M.” “S” means an operation of displaying the vertical or horizontal bar on the display 20 without moving the vertical or horizontal bar, and “M” means an operation of displaying on the display 20 after moving the vertical or horizontal bar. “S” may mean a first value, and “M” may mean a second value.

When different walls come into contact with each other, the processor 11 may move and display the vertical or horizontal bar according to the information for determining whether to move the vertical or horizontal bar and display the vertical or horizontal bar on the display 20.

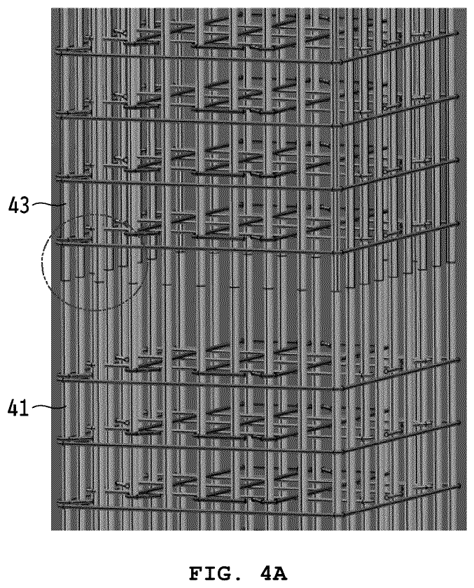

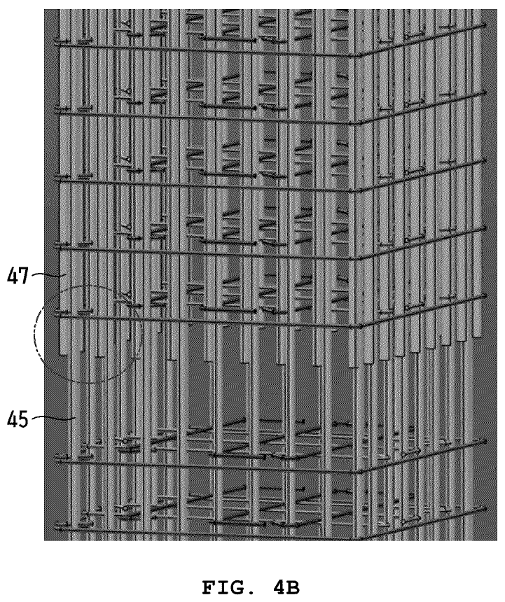

FIGS. 4A and 4B show columns displayed on the display of the computing device illustrated in FIG. 1 to describe other data of structural members. FIG. 4A shows steel bars 41 and 43 displayed on the display 20 of the computing device 10 when first steel bars 41 and second steel bars 43 forming a single column are aligned in a row without misalignment, and FIG. 4B shows steel bars 45 and 47 displayed on the display 20 of the computing device 10 when first steel bars 45 and second steel bars 47 forming a single column overlap with misalignment.

Referring to FIGS. 1 to 4, in some embodiments, when the structural members constitute a column, the defined data of the structural member may further include information for determining whether to move either, the steel bars 47, of the first steel bars 45 and the second steel bars 47 that form the column and display the steel bars 47 on the display 20. FIG. 3 shows a table in which walls are defined, and may include “S” or “M” for determining whether to move the structural members and display the structural members on the display 20 similar to the case of the walls even when the structural members constitute a column. The table in which the columns are defined is as follows.

TABLE 1

| | Design drawings | | Vertical bars | | | |
|---|---|---|---|---|---|---|
| Location | Material | Covering | Left | Right | Connection | |
| information | strength | thickness | shape | shape | location | Column definition |
| 001 | AB | NWLI | LB | RB | S | 001_ABNWLI_LBRB_S |
| 002 | AB | NWLI | LB | RB | M | 002_ABNWLI_LBRB_M |
| . . . | . . . | . . . | . . . | . . . | . . . | . . . |

In Table 1 above, “001_ABNWLI_LBRB_S” may mean the first steel bars 45 forming a column, and “002_ABNWLI_LBRB_M” may mean the second steel bars 47 forming the column. That is, the column is defined by specific properties of the steel bar (location information, material strength, covering thickness, member direction, left side of vertical bar, and right side of vertical bar).

The location information in Table 1 may be location information of the vertical bars. The location information of the vertical bars may include coordinates at which the column is located in the building. The location information of the vertical bars may include a height section in which the vertical bars are located in the column. The height section may be a range of values in which the vertical bars are arranged in the height direction of the column. The height direction of the column may be a direction in which the column extends. The processor 11 may determine the order in which the vertical bars are arranged in the height direction of the column using the height section of the vertical bars.

The first steel bars 45 and the second steel bars 47 may extend in the height direction of the column. The first steel bars 45 may be first vertical bars included in the column. The second steel bars 47 may be second vertical bars included in the column. In some embodiments, the first steel bars 45 may be vertical bars located in a height section included in “001” of the column, and the second steel bars 47 may be vertical bars located in a height section included in “002.”

The first steel bars 45 and the second steel bars 47 may be arranged adjacent to each other in the height direction of the column. In the defined data of the structural members, the height section included in the location information of the first steel bars 45 and the height section included in the location information of the second steel bars 47 may be adjacent to each other in the height direction of the column.

In some embodiments, the first steel bars 45 may be vertical bars located in a first height section from the bottom of the column, and the second steel bars 47 may be vertical bars located in a second height section from the bottom of the column.

In an actual construction site, for safety reasons, the first steel bars 41 and the second steel bars 43 forming a single column cannot be constructed in contact with each other as illustrated in FIG. 4A, and the first steel bars 45 and the second steel bars 47 should be constructed to overlap each other with misalignment as illustrated in FIG. 4B. In order to accurately identify the arrangement of the steel bars at the construction site, the first steel bars 45 and the second steel bars 47 should be expressed on the display 20 as illustrated in FIG. 4B. That is, either, the steel bars 47, of the first steel bars 45 and the second steel bars 47 forming a single column should be moved and displayed on the display 20 as illustrated in FIG. 4B.

To this end, the defined data of the structural members may further include information (“S” or “M”) for determining whether to move the steel bars 47 forming the column and display the steel bars 47 on the display 20. When there is no information for determining whether to move the steel bars 47 forming the column and display the steel bars 47 on the display 20, either the first steel bars 45 or the second steel bars 47 cannot be moved and displayed on the display 20. That is, when there is no information on the connection location in Table 1 above, either the first steel bars 45 or the second steel bars 47 cannot be moved and displayed on the display 20.

FIG. 4B shows the first steel bars 45 forming a single column that are displayed on the display 20 without being moved, and the second steel bars 47 forming the column that are moved and displayed on the display 20. In the present invention, even when locations of the second steel bars 47 change, a location of the column does not change.

The information for determining whether to move the vertical bars included in the column and display the vertical bars on the display 20 has different values sequentially according to the location information. Specifically, the information for determining whether to move each of the vertical bars forming the column and display the vertical bars on the display 20 may be alternately set for each of the vertical bars sequentially located in the height direction of the column. In some embodiments, “S” and “M” may be set to alternately correspond to the vertical bars sequentially located in the height direction of the column.

When complexly densely packed steel bars are simply displayed overlapping, there is a problem in that it is difficult to accurately identify the individual location, length, interval, and interference with adjacent steel bars of each steel bar with the naked eye. The alternating display of the present invention may help a user clearly recognize information on individual steel bars and immediately identify interference and construction errors with the naked eye by showing the steel bars spatially separated.

The alternating display enables such potential errors to be intuitively identified from the design stage and immediate design modifications may be made, thereby significantly reducing unnecessary rework and costs.

In some embodiments, when the information for determining whether to move the first steel bars 45 and display the first steel bars 45 on the display 20 includes “S,” the information for determining whether to move the second steel bars 47 and display the second steel bars 47 on the display 20 may include “M,” and the information for determining whether to move third steel bars (not illustrated) and display the third steel bars on the display 20 may include “S.” The third steel bars are steel bars located above the second steel bars 47. In some embodiments, the third steel bars may be vertical bars located in a third height section from the bottom of the column. “M” means that the steel bars are moved and displayed on the display 20, and “S” means that the steel bars are displayed on the display 20 without being moved.

When a value corresponding to the second steel bars 47 is “M,” the second steel bars 47 may be moved to be misaligned with the first steel bars 45 in the height direction of the column but overlap at least a portion of the first steel bars 45, and may be displayed on the display 20. In some embodiments, a portion of an upper side of the first steel bars 45 and a portion of a lower side of the second steel bars 47 may overlap.

Further, when a value corresponding to the second steel bars 47 is “M,” the second steel bars 47 may be moved to be misaligned with the third steel bars in the height direction of the column but overlap at least a portion of the third steel bars, and may be displayed on the display 20. In some embodiments, a portion of an upper side of the second steel bars 47 and a portion of a lower side of the third steel bars may overlap.

When the information for determining whether to move the first steel bars 45 and display the first steel bars 45 on the display 20 includes “M,” the information for determining whether to move the second steel bars 47 and display the second steel bars 47 on the display 20 includes “M,” and the information for determining whether to move the third steel bars (not illustrated) and display the third steel bars on the display 20 includes “M,” there is a problem in that all the steel bars are displayed on the display 20 to be inclined in one direction.

In some embodiments, the information for determining whether to move the steel bars and display the steel bars on the display 20 may be set by the computing device 10 so that “S” and “M” alternately correspond to vertical bars sequentially located in the height direction of the column. In some embodiments, the information for determining whether to move the steel bars and display the steel bars on the display 20 may be set by a user who uses the computing device 10.

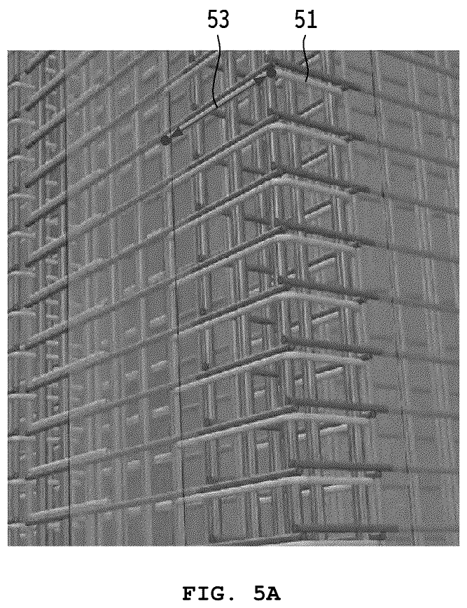

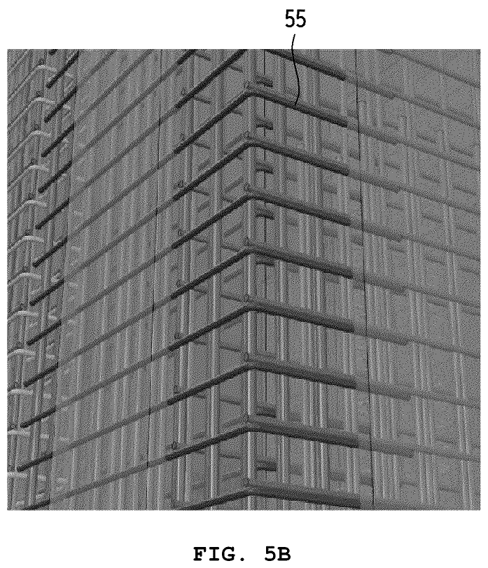

FIGS. 5A and 5B show walls displayed on the display of the computing device illustrated in FIG. 1 to describe still other data of the structural members. FIG. 5A shows a wall displayed as U-bars on the display. FIG. 5B shows a wall displayed as hooks on the display.

Referring to FIGS. 1 to 5, the processor 11 determines whether a wall is in contact with another wall using location information. When it is determined that different walls overlap each other using location information on the walls, the processor 11 determines that the walls are in contact with each other.

When it is determined that the wall is not in contact with another wall, that is, when it is determined that the wall is a corner of the building, the processor 11 generates information on U-bars 51 for the wall and displays the U-bars 51 on the display 20.

The information on the U-bars 51 includes a length 53 of the U-bars 51.

The processor 11 extracts the information on the strength of steel bars used in the wall defined in the design drawings, specifies the type of steel bars used in the defined wall among the plurality of steel bars according to the extracted information on the strength of the steel bars, checks the joint length of the U-bars according to the type of steel bars, and determines a joint length of the U-bars as the length 53 of the U-bars 51. In some embodiments, the processor 11 extracts a steel bar of 500 MPa, which is a steel bar of HD16 or lower, from the design drawings as the information on the strength of the steel bar, selects specific steel bars (e.g., HD13) used in the wall from among the plurality of steel bars according to the strength of the extracted steel bar of 500 MPa, checks the joint length of the U-bars according to the specific steel bars (e.g., HD13), and determines the joint length of the U-bars as the length 53 of the U-bars 51.

The information on the U-bars for the wall may be included in the defined data of the structural members. The information on the U-bars for the wall may be indicated as “X” or “Y.” The information on the U-bars for the wall may be set by the user who uses the computing device 10. That is, the user may select “X” or “Y” for the information on the U-bars for the wall.

When the information on the U-bars for the wall is “Y,” the U-bars are displayed on the display 20 as illustrated in FIG. 5A.

When the information on the U-bars for the wall is “X,” the hooks are displayed on the display 20 as illustrated in FIG. 5B instead of the U-bars. When the information on the U-bars for the wall is “X,” the processor 11 executes commands that are performed so that the hooks are displayed on the display 20 as illustrated in FIG. 5B instead of the U-bars displayed as illustrated in FIG. 5A.

A function for displaying the U-bars or hooks illustrated in FIG. 5 helps workers at construction sites accurately recognize the steel bars at an end of the wall and perform construction, thereby contributing to preventing omissions or incorrect steel bar arrangement that may occur during the steel bar arrangement. This has a direct impact on securing the structural safety of the building.

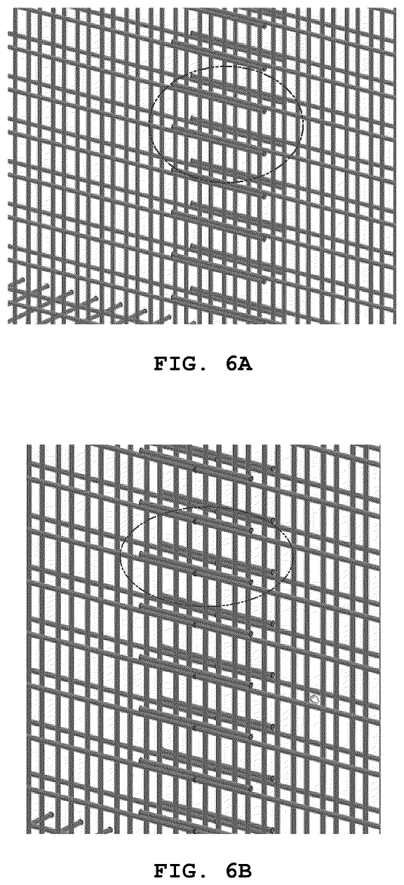

FIGS. 6A and 6B show walls displayed on the display of the computing device illustrated in FIG. 1 to describe yet other data of the structural members.

Referring to a red circle in FIG. 6A, a state in which different steel bars overlap each other in the wall is illustrated.

Referring to a red circle in FIG. 6B, a state in which different steel bars are in contact with each other in the wall is illustrated. In the case in which different steel bars are in contact with each other as illustrated in FIG. 6B, in order to strengthen the bonding strength of the steel bars, one more separate steel bar is bonded to overlap the steel bars that are in contact with each other.

Referring to FIGS. 1 to 6, in some embodiments, the defined data of the structural members may further include information on a connection relationship between the steel bars displayed on the display 20. The information on the connection relationship between the steel bars displayed on the display 20 may indicate a connection relationship between steel bars forming a wall.

In some embodiments, when the information on the connection relationship between the steel bars displayed on the display 20 in the defined data of the structural members includes “C,” a state like that in FIG. 6A may be displayed on the display 20. When the information on the connection relationship between the steel bars displayed on the display 20 in the defined structural members includes “D,” a state like that in FIG. 6B may be displayed on the display 20. “C” may mean a third value, and “D” may mean a fourth value.

In some embodiments, the information on the connection relationship between the steel bars displayed on the display 20 may be set by the user who uses the computing device 10. That is, the user may select “C” or “D” as the information on the connection relationship between the steel bars displayed on the display 20 so that a state in which different steel bars overlap each other in the wall as illustrated in FIG. 6A or a state in which different steel bars are in contact with each other as illustrated in FIG. 6B is displayed on the display 20.

Specifically, when the connection relationship between the steel bars displayed on the display 20 includes “C,” two steel bars that are arranged adjacently and coupled to each other may be displayed on the display so that the two steel bars are misaligned in one direction but at least portions thereof overlap each other. When the connection relationship between the steel bars displayed on the display 20 includes “D,” the two steel bars may be displayed on the display so that the two steel bars are in contact with each other in one direction but a reinforcing steel bar is added to the contact area.

In some embodiments, the lengths of the steel bars in FIGS. 6A or 6B may be changed. As the lengths of the steel bars are changed, the location of the connection relationship between the steel bars may be changed. The location of the red circle in FIG. 6A may be changed. The location at which different steel bars are connected may be changed. The location of the red circle in FIG. 6B may be changed. The location at which a separate steel bar is further connected may be changed.

A function for displaying the connection state of the steel bars illustrated in FIG. 6 allows a construction worker to clearly understand a method of connecting steel bars (overlapping/contacting and reinforcing), thereby preventing steel bar joint defects or construction errors during on-site construction. This function acts as a technical means that substantially improves construction quality beyond simple visual expression.

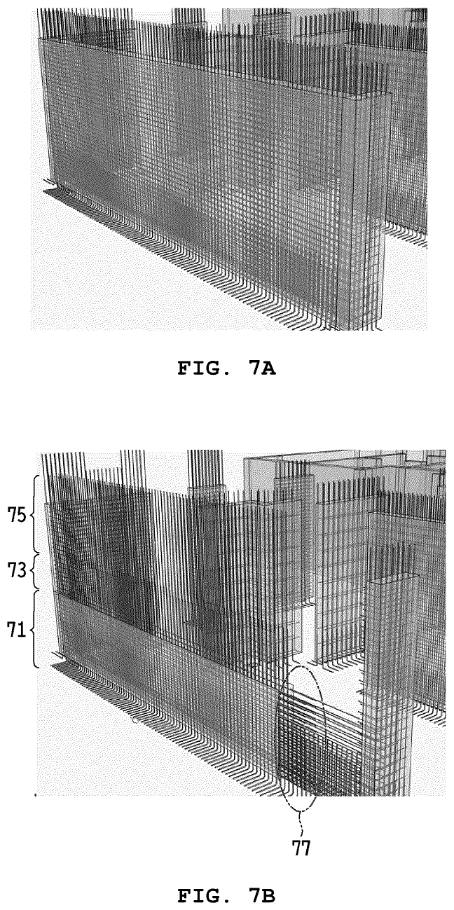

FIGS. 7A and 7B shows walls displayed on the display of the computing device illustrated in FIG. 1 to describe yet other data of the structural members.

Referring to FIGS. 1 to 7, FIG. 7A shows a 3D-modeled wall displayed on the display 20. FIG. 7B shows a 3D-modeled wall displayed on the display 20 when a user sets an amount of work to be done during a certain period of time (e.g., one day, one week, one month, etc.). The amount of work to be done means the scope of the work.

Referring to FIG. 7A, the 3D-modeled wall is displayed on the display 20. The 3D-modeled wall may be transmitted from the computing device 10 to an electronic device (not illustrated) used at the construction site via a network (not illustrated). A user (e.g., a site manager) who uses the electronic device at the construction site may determine the scope of work to be performed each day. A scope of work is defined by the computing device 10 as a numerical range having a range between a first arbitrary number (e.g., 10) and a second arbitrary number (e.g., 10,000). The scope of work means the length of the wall. The determination of the scope of work may be performed by the computing device 10.

The scope of work may be set by the user who uses the computing device 10. Steel bars 71 to be arranged according to the scope of work determined by the user are displayed in a first color (e.g., green). Further, steel bars 75 to be arranged outside the scope of work determined by the user are displayed in a second color (e.g., gray). Further, steel bars 73 and 77 for connecting the steel bars 71 to be arranged according to the scope of work determined by the user to the steel bars 75 to be arranged outside the scope of work determined by the user are additionally displayed in the first color (e.g., green). The steel bars 73 and 77 may not be illustrated in FIG. 7A. In some embodiments, the steel bars 73 and 77 may be displayed in a third color (e.g., red).

When the steel bars 73 and 77 are illustrated as in FIG. 7B, the arrangement of steel bars required at an actual construction site may be accurately expressed. When the steel bars 73 and 77 are not illustrated as in FIG. 7B, problems will occur in the future in that it will not be known how to connect the steel bars in relation to construction.

A work schedule-based steel bar arrangement display function illustrated in FIG. 7 supports contractors in intuitively checking the range of steel bars to be arranged over a certain period of time and planning the construction work. This improves the efficiency and accuracy of the construction process and provides practical technical effects in construction quality management. Further, such information is transmitted to construction auxiliary equipment such as tablets used at construction sites and directly utilized in on-site work.

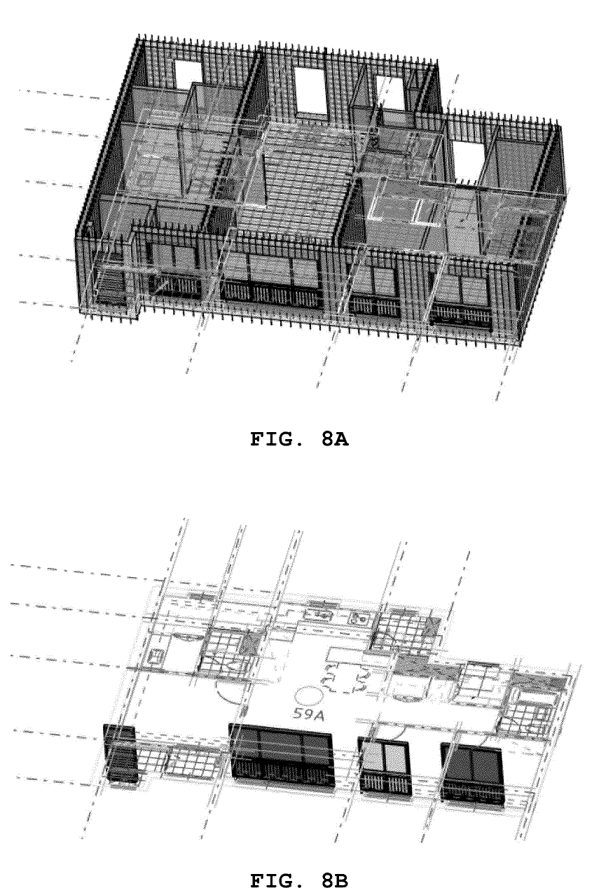

FIGS. 8A, 8B, and 8C show walls displayed on the display of the computing device illustrated in FIG. 1 to describe structural members that are changed when the design of the building is changed.

FIG. 8A shows the structural members that are displayed on the display before the design of the building is changed. FIG. 8B shows the building in which the structural members of the building before the change disappear from the display when the design of the building is changed. FIG. 8C shows the structural members that are changed on the display after the change when the design of the building is changed.

Referring to FIGS. 1 to 8, the processor 11 displays part or all of the building in 3D on the display 20 according to the defined structural members, as illustrated in FIG. 8A.

The user who uses the computing device 10 may change an area of the building or an area of the floor of the building, in the building displayed on the display 20 as illustrated in FIG. 8A. The change of the building means expansion or reduction of the building.

That is, the method for 3D modeling of the structural members of the building may further include commands that can change the area of the building or the area of the floor of the building. That is, an interface that allows the user who uses the computing device 10 to change the area of the building or the area of the floor of the building may further be implemented. In some embodiments, the interface may be an interface that can display a current area of the building and change the current area of the building. The current area of the building may include a length in an X-axis direction and a length in a Y-axis direction.

When the area of the building or the area of the floor of the building is changed by the user who uses the computing device 10, the processor 11 may make a plurality of first structural members (e.g., walls) present in the original building invisible on the display 20. The plurality of first structural members (e.g., walls) present in the original building may be sequentially removed from the display 20. This may be illustrated on the display 20 as illustrated in FIG. 8B. In this case, the walls are invisible on the display 20 but windows or doors may continue to be visible on the display 20.

The processor 11 checks location information corresponding to the area of the building changed on the display 20, automatically rearranges a plurality of second structural members (e.g., walls) according to the checked location information, and displays the plurality of rearranged second structural members on the display 20. In this case, information on the shapes of the steel bars included in the walls may vary. In some embodiments, the information on the shapes of the steel bars in FIG. 2 may be changed from “EE” to “LB.”

Specifically, the processor 11 calculates a ratio of the area of the building before the change, that is, an area of the original building, to an area of the changed building on the display 20. In some embodiments, when the area of the original building is 1 and the area of the changed building is 1.5, the processor 11 calculates 1.5 as the ratio of the area of the original building to the area of the changed building.

The processor 11 rearranges locations of the windows that were present in the original building according to the calculated ratio of the area of the original building to the area of the changed building, and displays the rearranged locations of the windows on the display 20.

A specific method of rearranging the windows is as follows.

The processor 11 calculates a distance between the windows that were present in the original building.

The processor 11 sets a new distance between the windows in the changed building by multiplying the calculated distance between the windows by the ratio of the area of the original building to the area of the changed building. In some embodiments, when a distance between window A and window B that were present in the original building is 5 cm and a ratio of the area of the original building to the area of the changed building is 1.5, the processor 11 sets 7.5 cm as the distance between window A and window B in the new building. In this case, a location of window A may not be changed and a location of window B may be changed. Further, both the location of window A and the location of window B may be changed. Window A or window B is a window that is present in a specific location in the building.

The processor 11 rearranges the plurality of second structural members (e.g., walls) into the distance between the newly set windows, and displays the plurality of rearranged second structural members on the display 20. That is, the steel bars are rearranged.

Each of the plurality of first structural members and plurality of second structural members relates to a wall and may include data including location information, information on the extracted material strength or covering thickness, information on the shapes of the steel bars, and information for determining whether to move vertical bars or horizontal bars and display the vertical bars or the horizontal bars on the display 20.

When the change of the area of the building is an expansion of an area of a previous building, the processor 11 may define data of the plurality of first structural members as data of new structural members, and define the plurality of existing first structural members and the new structural members as the plurality of second structural members.

The data of the new structural members includes data of any one of the plurality of first structural members, that is, the information on the material strength and covering thickness, the information on the shapes of the steel bars, and the information for determining whether to move the vertical bars or the horizontal bars and display the vertical bars or the horizontal bars on the display 20 without change. However, with respect to the location information among the data, the location information of the new structural members and the location information of any one of the plurality of first structural members are different from each other. The processor 11 extracts the extended location information from the display 20 and defines the extracted location information as the location information of the new structural members.

In some embodiments, when any one of the plurality of first structural members is a wall 002_ABNWLI_X_LBRB_S_LIBLOB_M defined in FIG. 3, the processor 11 may define “AB,” “NWLI,” “X,” “LB,” “RB,” “S,” “LIB,” “LOB,” and “M” as the data of the new structural members.

In some embodiments, when any one of the plurality of first structural members is a wall 001_ABNWLI Y_LBRB_S_EEEEEE_S defined in FIG. 3, the processor 11 may define “AB,” “NWLI,” “Y,” “LB,” “RB,” “S,” “EEE,” “EEE,” and “S” as the data of the new structural members.

A design change response function illustrated in FIG. 8 is not limited to a simple visual update function, but also supports a flow in which the data of the changed structural members is transmitted to the construction site and directly reflected in the construction process.

The results of the rearrangement of the structural members due to the design changes may be checked in real time on the display, and this data is transmitted to field workers through construction assistance equipment and used in actual construction work. This prevents construction errors and confusion when the design is changed, and enables construction that reflects the latest design status.

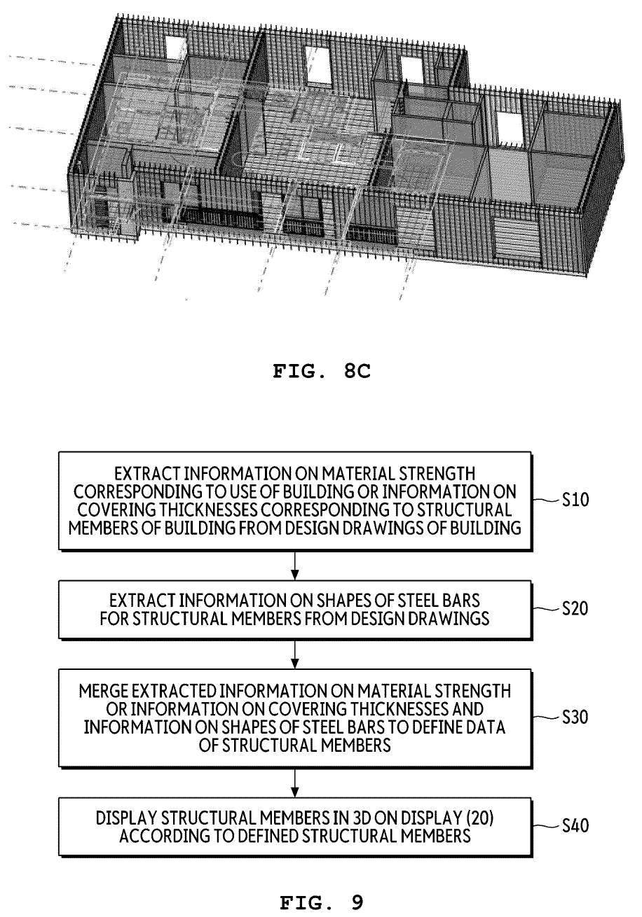

FIG. 9 illustrates a flowchart for describing a method for 3D modeling of structural members of a building of the present invention.

Referring to FIGS. 1 to 9, the processor 11 extracts information on a material strength corresponding to the use of the building or information on covering thicknesses corresponding to the structural members of the building from the design drawings of the building (S10).

The processor 11 extracts information on the shapes of steel bars for the structural members from the design drawings (S20).

The processor 11 merges the extracted information on the material strength or information on the covering thicknesses and information on the shapes of the steel bars to define data of the structural members (S30).

The processor 11 displays the structural members in 3D on the display 20 according to the defined structural members (S40).

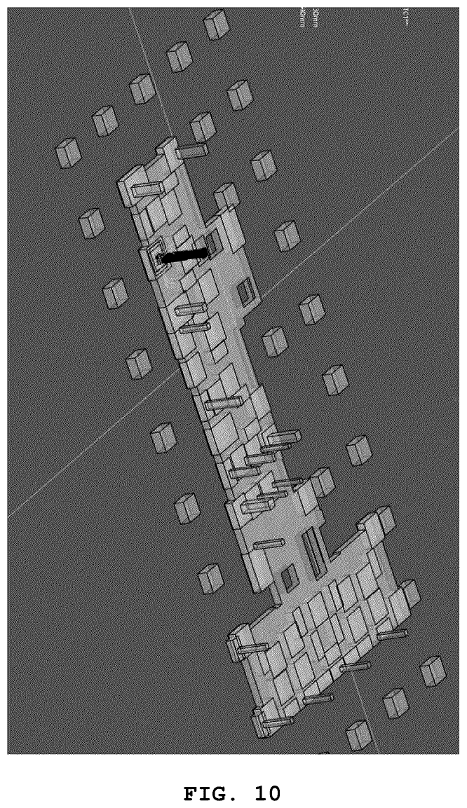

FIG. 10 shows 3D-modeled structural members of the building displayed on the display illustrated in FIG. 1.

Referring to FIGS. 1 to 10, 3D-modeled structural members of the building (e.g., columns, foundations, floors, etc.) displayed on the display 20 are illustrated.

According to a method and device for 3D modeling of structural members of a building according to embodiments of the present invention, it is possible to define data of the structural members of the building and 3D-model the structural members according to the defined data of the structural members, thereby enabling design errors to be immediately identified, and immediately reflecting the material change even when materials and the like are changed on site.

According to the method and device for 3D modeling of the structural members of the building according to the embodiments of the present invention, it is possible to significantly improve the visual recognizability of individual steel bars through an alternate display method, and enable early and intuitive discovery and correction of potential design errors, such as interference between steel bars and insufficient covering thicknesses, that may occur during the design stage, thereby increasing design accuracy and minimizing rework.

In some embodiments, the present invention may be applied to automate three-dimensional (3D) modeling for a variety of structural and construction elements in a building project. Examples of applicable targets for the proposed 3D modeling automation include, but are not limited to, slabs with rebar and concrete, columns with rebar and concrete, beams with rebar and concrete, and walls with rebar and concrete. The system may further support block modeling and quantity take-off for masonry works or partition walls. Additionally, temporary works such as scaffolding, shoring, and formwork can also be modeled in three dimensions to enhance construction planning, site safety, and material management.

By automating the generation of detailed 3D models for these various structural elements, the invention enables improved design accuracy, early detection of clashes or construction errors, and efficient response to on-site variations. This comprehensive modeling capability contributes to the reduction of rework, improved cost estimation, and enhanced overall constructability of complex building projects.

While the present invention has been described with reference to the embodiment illustrated in the accompanying drawings, the embodiment should be considered in a descriptive sense only, and it should be understood by those skilled in the art that various alterations and other equivalent embodiments may be made. Therefore, the scope of the present invention should be defined by the appended claims.

What is claimed is:

1. A method for three-dimensional (3D) modeling of structural members of a building, which is performed by a processor, comprising:
extracting at least one of information on a material strength corresponding to use of the building and information on covering thicknesses of steel bars corresponding to the structural members of the building from a design drawing of the building;
extracting information on shapes of the steel bars for the structural members from the design drawing;
extracting location information on the structural members from the design drawing; and
defining at least one of the information on the material strength, the information on the covering thicknesses, the information on the shapes of the steel bars, and the location information as data of the structural members,
wherein, when the structural members constitute a column, the data of the structural members corresponds to the steel bars extending in a height direction of the column, and includes first information for determining whether to move the steel bars forming the column and display the steel bars on a display, and
the first information includes a first value that is displayed on the display without moving the steel bars and a second value that is displayed on the display after moving the steel bars, and is set so that the first value and the second value alternately correspond to the steel bars sequentially located in the height direction of the column.

2. The method of claim 1, wherein the location information includes:
coordinates of a location at which the column is located in the building; and
a height section in which the steel bars are located in the column,
wherein the height section is a range of values in which the steel bars are arranged in the height direction of the column, and
the method further includes determining an order in which the steel bars are arranged in the height direction of the column using the height section of the steel bars.

3. The method of claim 1, wherein the steel bars forming the column include first steel bars and second steel bars that are adjacent to each other in the height direction of the column, and
when the first value corresponds to the first steel bars and the second value corresponds to the second steel bars, the second steel bars are moved to be misaligned with the first steel bars in the height direction of the column but overlap at least a portion of the first steel bars, and are displayed on the display.

4. The method of claim 1, wherein the information on the shapes of the steel bars includes a shape in a first direction of the steel bars and a shape in a second direction of the steel bars,
the shape in the first direction of the steel bar is a shape of the steel bar in a direction into the display among the steel bars, and includes one of shapes included in a steel bar shape database in which shapes of vertical bars and shapes of horizontal bars are stored, and
the shape in the second direction of the steel bar is a shape of the steel bar in a direction out of the display among the steel bars, and includes one of the shape included in the steel bar shape database.

5. The method of claim 1, wherein, when the structural members constitute a wall, the data of the structural members further includes second information on a connection relationship between the steel bars forming the wall,
wherein the second information includes at least one of a third value that is displayed on the display so that two steel bars that are arranged adjacently and coupled to each other are misaligned with each other in one direction but at least portions thereof overlap each other, and a fourth value that is displayed on the display so that the two steel bars are in contact with each other in the one direction but a reinforcing steel bar is added to the contact area.

6. A computing device comprising:
a memory configured to store commands for three-dimensional (3D) modeling of structural members of a building; and
a processor configured to execute the commands,
wherein the commands are configured to:
extract at least one of information on a material strength corresponding to use of the building and information on covering thicknesses of steel bars corresponding to the structural members of the building from a design drawing of the building,
extract information on shapes of the steel bars for the structural members from the design drawing,
extract location information on the structural members from the design drawing, and
define at least one of the information on the material strength, the information on the covering thicknesses, the information on the shapes of the steel bars, and the location information as data of the structural members,
wherein, when the structural members constitute a column, the data of the structural members corresponds to the steel bars extending in a height direction of the column, and includes first information for determining whether to move the steel bars forming the column and display the steel bars on a display, and
the first information includes a first value that is displayed on the display without moving the steel bars and a second value that is displayed on the display after moving the steel bars, and is set so that the first value and the second value alternately correspond to the steel bars sequentially located in the height direction of the column.

7. The computing device of claim 6, wherein the location information includes:
coordinates of a location at which the column is located in the building; and
a height section in which the steel bars are located in the column,
wherein the height section is a range of values in which the steel bars are arranged in the height direction of the column, and
the commands are configured to determine an order in which the steel bars are arranged in the height direction of the column using the height section of the steel bars.

8. The computing device of claim 6, wherein the steel bars forming the column include first steel bars and second steel bars that are adjacent to each other in the height direction of the column, and
when the first value corresponds to the first steel bars and the second value corresponds to the second steel bars, the commands are configured so that the second steel bars are moved to be misaligned with the first steel bars in the height direction of the column but overlap at least a portion of the first steel bars, and are displayed on the display.

9. The computing device of claim 6, wherein the memory includes a steel bar shape database in which shapes of vertical bars and shapes of horizontal bars are stored,
the information on the shapes of the steel bars includes shapes in a first direction of the steel bars and shapes in a second direction of the steel bars,
the shape in the first direction of the steel bar is a shape of the steel bar in a direction into the display among the steel bars, and includes one of the shapes included in the steel bar shape database, and
the shape in the second direction of the steel bar is a shape of the steel bar in a direction out of the display among the steel bars, and includes one of the shapes included in the steel bar shape database.

10. The computing device of claim 6, wherein, when the structural members constitute a wall, the data of the structural members further includes second information on a connection relationship between the steel bars forming the wall,
wherein the second information includes at least one of a third value that is displayed on the display so that two steel bars that are arranged adjacently and coupled to each other are misaligned with each other in one direction but at least portions thereof overlap each other, and a fourth value that is displayed on the display so that the two steel bars are in contact with each other in the one direction but a reinforcing steel bar is added to the contact area.
